(19) United States
(12) Patent Application Publication
(10) Pub. No.: US 2005/0239420 A1
(43) Pub. Date: Oct. 27, 2005

(54) Rf amplifier system with interface to provide a computer readable spectral depiction of the rf output

(76) Inventor: Ki Y. Nam, Newport Beach, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/506,714

(22) PCT Filed: Mar. 6, 2003
(86) PCT No.: PCT/US03/07092

§ 371 Date: Sep. 7, 2004

Related U.S. Application Data
(60) Provisional application No. 60/362,295, filed on Mar. 6, 2002.
(60) Provisional application No. 60/362,503, filed on Mar. 6, 2002.

(51) Int. Cl. H03C 1/62; H04B 17/00; H04B 1/04

(52) U.S. Cl. 455/115.1; 455/126; 455/127.1

(57) ABSTRACT

An RF amplifier system includes an RF power amplifier, a coupler, a digital signal analysis circuit, and an interface. The RF power amplifier has an RF output. The coupler is coupled to the RF power amplifier to detect the RF output. The digital signal analysis circuit is coupled to the coupler to produce a digital signal that provides a spectral depiction of the RF output. The interface is coupled to the digital signal analysis circuit to provide the spectral depiction of the RF output to an attached computer.

### CROSS REFERENCE TO RELATED APPLICATIONS

This application claims the benefit of U.S. Provisional Application No. 60/362,295, filed Mar. 6, 2002 and of U.S. Provisional Application No. 60/362,503, filed Mar. 6, 2002.

### BACKGROUND OF THE INVENTION

RF amplifier systems may be used to amplify radio frequency (RF) signals for over the air broadcasting. RF amplifier systems are used at cellular telephone sites which may be in remote locations. It may be necessary to monitor the output of an RF amplifier system to ensure that it is performing properly and in compliance with applicable broadcasting regulations. It may be very costly to dispatch a technician to a remote site for routine testing. Even if the site of the RF amplifier system is convenient, it is costly and time consuming to dispatch a technician with the necessary skills to correctly test the output of an RF amplifier system. These limitations may cause the RF amplifier system to operate improperly or out of compliance for a substantial period of time until a technician visits the site of the RF amplifier system to monitor the output of the system.

### SUMMARY OF THE INVENTION

An RF amplifier system includes an RF power amplifier, a coupler, a digital signal analysis circuit, and an interface. The RF power amplifier has an RF output. The coupler is coupled to the RF power amplifier to detect the RF output. The digital signal analysis circuit is coupled to the coupler to produce a digital signal that provides a spectral depiction of the RF output. The interface is coupled to the digital signal analysis circuit to provide the spectral depiction of the RF output to an attached computer.

### BRIEF DESCRIPTION OF THE DRAWINGS

FIG. 1 is a block circuit diagram of an exemplary RF amplifier system that embodies the present invention.

FIG. 2 is a block circuit diagram of another exemplary RF amplifier system that embodies the present invention.

FIG. 3 is a block circuit diagram of an exemplary digital signal analysis circuit that may be used in an embodiment of the present invention.

FIG. 4 is a block circuit diagram of another exemplary digital signal analysis circuit that may be used in an embodiment of the present invention.

### DETAILED DESCRIPTION OF THE INVENTION

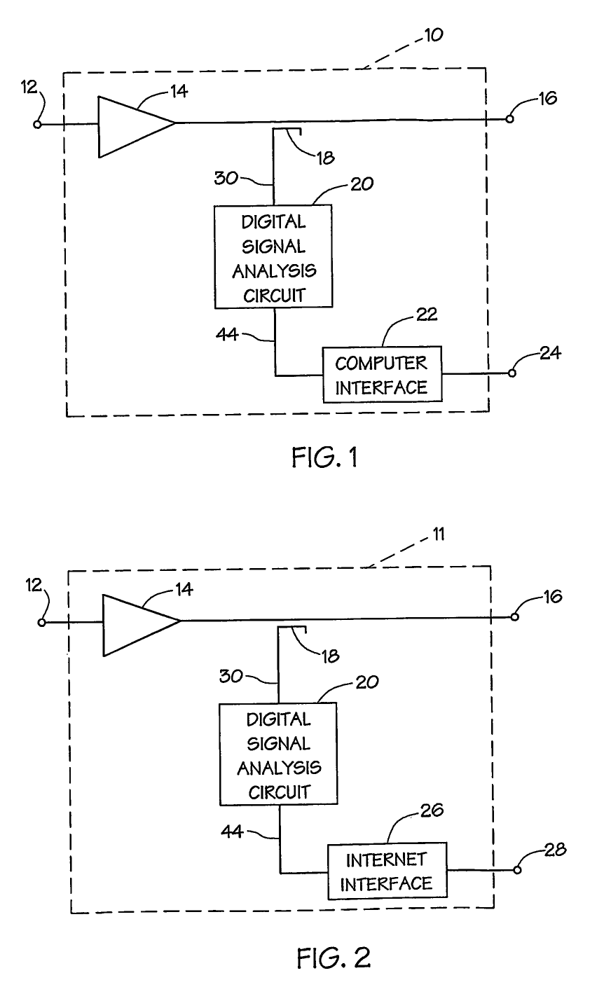

FIG. 1 shows an RF amplifier system 10 that embodies the present invention. The RF amplifier system 10 receives an RF input 12 and produces an RF output 16 that is the result of amplifying the RF input with an RF power amplifier 14. A coupler 18 detects the output 16 of the RF power amplifier 14 and feeds the detected signal into a digital analysis circuit 20 that produces a digital analysis of the spectral output of the RF power amplifier 14.

The digital analysis produced by the digital analysis circuit 20 is then converted by a computer interface 22 to a form that can be read by a computer connected to the interface output 24. The computer may display or print an X vs. Y plot of the output of the digital signal analysis circuitry to provide a spectral depiction of the output of the RF power amplifier 14. By integrating the RF power amplifier 14, the coupler 18, the digital analysis circuit 20, and the computer interface 22 in the single chassis of the RF amplifier system 10, the proper selection of coupler and analysis circuit for the RF power amplifier and the proper connection is assured. This may allow maintenance and servicing of the RF amplifier system 10 more quickly and by technicians with a lower skill requirement.

FIG. 2 shows another RF amplifier system 11 that embodies the present invention. In this embodiment the digital analysis produced by the digital analysis circuit 20 is converted by an Internet Protocol (IP) interface 26 to a form that can be communicated over long distances on the internet by coupling the interface output 28 to the internet. A remotely located computer may access the RF amplifier system 11 using an internet connection to read, display, or print a spectral depiction of the output of that RF power amplifier 14. This may allow the operation of the RF amplifier system 11 to be monitored for correct operation without the need to send a technician to the site of the RF amplifier system on a routine basis. Remote monitoring may allow an initial diagnosis of detected faults so that a properly equipped technician can be dispatched to effect a repair of the RF amplifier system 11. A single RF amplifier system may include both the computer interface 22 and the IP interface 26 and provide both the computer interface output 24 for local service and the IP interface output 28 for remote monitoring.

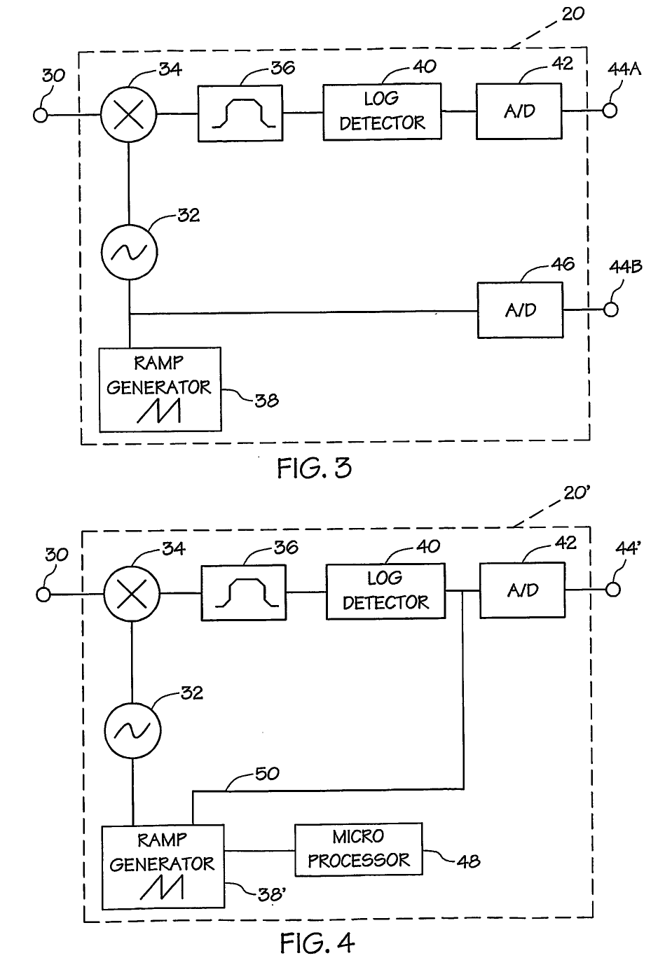

FIG. 3 shows an exemplary embodiment of the digital analysis circuit 20. The detected signal 30 from the coupler 18 (FIGS. 1 and 2) is mixed down in frequency via a voltage controlled oscillator (VCO) 32, a mixer 34, and a filter 36. A ramp generator 38 feeds the VCO 32 with a varying voltage. The output of the filter 36 is coupled to a log detector 40.

The resulting analog output of the log detector 40 is digitally converted via a low speed, low cost analog-to-digital (A/D) converter 42 to provide a “Y” (magnitude) portion of an output signal 44a. The analog DC voltage output of the ramp generator 18 that is provided to the VCO 32 is also converted via a second low speed, low cost, A/D converter 46 to provide an “X” (frequency) portion of the output signal 44b. An X vs. Y plot of the output signal 44 from the digital analysis circuit 20, via electrical or mechanical means, may result in a spectral depiction of the RF output 16 of the RF amplifier system.

FIG. 4 shows another exemplary embodiment of the digital analysis circuit 20. In this embodiment, the detected signal 30 from the coupler 18 is mixed down with the signal from the VCO 32 as in the previous embodiment. A microprocessor 48 or controller instructs the ramp generator 38′ to additionally output a blanking or “0” signal 50 of a known interval simultaneously with the zero VDC point of the signal from the ramp generator 38′. The blanking signal 50 is fed into the output of the log detector 40. The resulting analog output of the log detector 40 is digitally converted via a low speed, low cost A/D converter 42 to become the “Y” (magnitude+time) output signal 44. The blanking signal contained within the Y (magnitude+time) output may then be extracted and used to represent the flow of the X (time) portion of an X vs. Y plot that is a spectral depiction of the RF output 16 of the RF amplifier system.

An RF amplifier system 10 that embodies the present invention may permit local or remote monitoring of the RF output for overall or per-channel power output, spurious signals or other forms of distortion, or to check any other performance parameter where the information is contained within the spectral depiction. The invention may further permit local or remote monitoring of the RF output of a cellular telephone site for conformance to power output, emissions mask specifications, or to check any other performance parameter where the information is contained with the spectral depiction.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

1. An RF amplifier system comprising:
an RF power amplifier having an RF output;
a coupler coupled to the RF power amplifier to detect the RF output;
a digital signal analysis circuit coupled to the coupler to produce a digital signal that provides a spectral depiction of the RF output; and
an interface coupled to the digital signal analysis circuit to provide the spectral depiction of the RF output to an attached computer.

2. The RF amplifier system of claim 1, wherein the digital signal analysis circuit further comprises:
a ramp generator;
a voltage controlled oscillator (VCO) coupled to the ramp generator;
a mixer coupled to the coupler and to the VCO;
a filter coupled to the mixer;
a log detector coupled to the filter; and
an analog-to-digital converter coupled to the log detector.

3. The RF amplifier system of claim 2, wherein the digital signal analysis circuit further comprises a second analog-to-digital converter coupled to the ramp generator in parallel with the VCO.

4. The RF amplifier system of claim 2, wherein the ramp generator is further coupled to the analog-to-digital converter and the ramp generator produces a blanking signal of a known interval simultaneously with a zero VDC point of a signal from the ramp generator that is fed into the output of the log detector.

5. The RF amplifier system of claim 4, further comprising a microprocessor that is coupled to the ramp generator to control the production of the blanking signal.

6. The RF amplifier system of claim 1, wherein the interface is a computer interface to provide the spectral depiction of the RF output that can be read by a connected computer.

7. The RF amplifier system of claim 1, wherein the interface is an internet interface to provide the spectral depiction of the RF output that can be read by a computer connected to the interface output by an internet connection.

8. A method of providing an a spectral depiction of an RF output from an RF amplifier system, the method comprising:
coupling to the RF output of an RF power amplifier in the RF amplifier system to detect the RF output;
performing digital signal analysis to produce a digital signal that provides a spectral depiction of the RF output; and
providing an interface on the RF amplifier system that allows a computer to be connected to the RF amplifier system to obtain the spectral depiction of the RF output.

9. The method of claim 8, wherein performing digital signal analysis further comprises:
generating a ramp voltage;
controlling a frequency of an oscillator signal with the ramp voltage;
mixing the detected RF output with the oscillator signal to produce a mixed signal;
filtering the mixed signal;
logarithmically detecting the filtered signal; and
converting the analog logarithmically detected signal to the spectral depiction of the RF output.

10. The method of claim 9, wherein performing digital signal analysis further comprises converting the ramp voltage to the spectral depiction of the RF output.

11. The method of claim 9, wherein performing digital signal analysis further comprises producing a blanking signal of a known interval simultaneously with a zero VDC point of the ramp voltage and feeding the blanking signal into the logarithmically detected signal.

12. The method of claim 8, wherein providing an interface on the RF amplifier system provides the spectral depiction of the RF output that can be read by a connected computer.

13. The method of claim 8, wherein providing an interface on the RF amplifier system provides the spectral depiction of the RF output that can be read by a computer connected to the interface output by an internet connection.

14. An RF amplifier system comprising:
an RF power amplifier means for producing an RF output;
a first means coupled to the RF power amplifier means for detecting the RF output;
a second means coupled to the first means for producing a digital signal that provides a spectral depiction of the RF output; and
a third means coupled to the third means for providing the spectral depiction of the RF output to an attached computer.

15. The RF amplifier system of claim 14, wherein the second means further comprises:
a ramp generator means for generating a ramp voltage;
a voltage controlled oscillator (VCO) means coupled to the ramp generator means for controlling a frequency of an oscillator signal with the ramp voltage;
a mixer means coupled to the first means and to the VCO means for mixing the detected RF output with the oscillator signal to produce a mixed signal;
a filter means coupled to the mixer means for filtering the mixed signal;
a log detector means coupled to the filter means for logarithmically detecting the filtered signal; and
an analog-to-digital converter means coupled to the log detector means for converting the analog logarithmically detected signal to the spectral depiction of the RF output.

16. The RF amplifier system of claim 15, wherein the second means further comprises a second analog-to-digital converter means coupled to the ramp generator means in parallel with the VCO means for converting the ramp voltage to the spectral depiction of the RF output.

17. The RF amplifier system of claim 15, wherein the ramp generator means is further coupled to the analog-to-digital converter means and the ramp generator means is further for producing a blanking signal of a known interval simultaneously with a zero VDC point of a signal from the ramp generator means that is fed into the output of the log detector means.

18. The RF amplifier system of claim 17, further comprising a microprocessor means that is coupled to the ramp generator means for controlling the producing of the blanking signal.

19. The RF amplifier system of claim 14, wherein the third means is for providing the spectral depiction of the RF output that can be read by a connected computer.

20. The RF amplifier system of claim 14, wherein the third means is for providing the spectral depiction of the RF output that can be read by a computer connected to the interface output by an internet connection.

21. An RF amplifier system comprising:
an RF power amplifier means for producing an RF output;
a first means for coupling to the RF output to detect the RF output;
a second means for performing digital signal analysis to produce a digital signal that provides a spectral depiction of the RF output; and
a third means for providing an interface on the RF amplifier system that allows a computer to be connected to the RF amplifier system to obtain the spectral depiction of the RF output.

22. The RF amplifier system of claim 21, wherein the second means further comprises:
a ramp generator means for generating a ramp voltage;
a voltage controlled oscillator (VCO) means for coupling to the ramp generator means to control a frequency of an oscillator signal with the ramp voltage;
a mixer means for coupling to the first means and to the VCO means to produce a mixed signal;
a filter means for coupling to the mixer means to filter the mixed signal;
a log detector means for coupling to the filter means to logarithmically detect the filtered signal; and
an analog-to-digital converter means for coupling to the log detector means to converting the analog logarithmically detected signal to the spectral depiction of the RF output.

23. The RF amplifier system of claim 22, wherein the second means further comprises a second analog-to-digital converter means for coupling to the ramp generator means in parallel with the VCO means to convert the ramp voltage to the spectral depiction of the RF output.

24. The RF amplifier system of claim 22, wherein the ramp generator means is further for coupling to the analog-to-digital converter means and the ramp generator means is further to produce a blanking signal of a known interval simultaneously with a zero VDC point of a signal from the ramp generator means that is fed into the output of the log detector means.

25. The RF amplifier system of claim 24, further comprising a microprocessor means for coupling to the ramp generator means to control the production of the blanking signal.

26. The RF amplifier system of claim 21, wherein the third means allows a computer to be connected by an internet connection.
